(19) United States
(12) Patent Application Publication
(10) Pub. No.: US 2017/0279288 A1
(43) Pub. Date: Sep. 28, 2017

(54) POWER-SUPPLY APPARATUS

(71) Applicant: Toyota Jidosha Kabushiki Kaisha, Toyota-shi (JP)

(72) Inventors: Masaru Kimura, Toyota-shi (JP); Noritake Mitsutani, Toyota-shi (JP)

(21) Appl. No.: 15/462,152

(22) Filed: Mar. 17, 2017

(30) Foreign Application Priority Data
Mar. 22, 2016 (JP) 2016-057195

(51) Int. Cl. H02J 7/00; G01R 19/165

(52) U.S. Cl. CPC H02J 7/0052; H02J 7/0068; G01R 19/165

(57) ABSTRACT

A power-supply apparatus includes: a battery; a charger that charges the battery; a charging relay provided on a power line to connect/disconnect the battery and the charger to/from each other through an on-off operation; a first voltage sensor attached to a portion of the power line between the charger and the charging relay; a second voltage sensor attached to a portion of the power line between the battery and the charging relay; and an ECU that permits detection of a deviation abnormality in which a deviation between a charger-side voltage and a battery-side voltage is equal to or greater than a threshold when it is verified that the battery is being charged by the charger while the charging relay is on, and prohibits the detection when it is not verified that the battery is being charged by the charger while the charging relay is on.

### CROSS-REFERENCE TO RELATED APPLICATIONS

This application claims priority to Japanese Patent Application No. 2016-057195 filed on Mar. 22, 2016, the entire contents of which are hereby incorporated by reference.

### BACKGROUND

### 1. Technical Field

The disclosure relates generally to a power-supply apparatus, and relates more specifically to a power-supply apparatus including a charger configured to charge a battery with externally-supplied electric power.

### 2. Description of Related Art

An example of this kind of power-supply apparatus is a power-supply apparatus in which a relay is attached to a power line that connects a battery and a charger to each other (see, for example, Japanese Unexamined Patent Application Publication No. 2011-160604 (JP 2011-160604 A)). In the power-supply apparatus, the relay is turned on when the charger charges the battery with electric power supplied from an external power supply. In this case, when a deviation between a voltage from a voltage sensor that is disposed closer to the charger than the relay is (hereinafter, referred to as “charger-side voltage sensor”) and a voltage from a voltage sensor that is disposed closer to the battery than the relay is (hereinafter, referred to as “battery-side voltage sensor”), is equal to or greater than a threshold, it is determined that a malfunction has occurred in the charger-side voltage sensor.

### SUMMARY

However, in the power-supply apparatus described above, when the power line breaks at a position that is closer to the battery than the charger-side voltage sensor is, the voltage from the charger-side voltage sensor increases and the deviation between the voltage from the charger-side voltage sensor and the voltage from the battery-side voltage sensor becomes equal to or greater than the threshold. In this case, it is determined that a voltage sensor malfunction has occurred, although the charger-side voltage sensor is actually not malfunctioning.

The disclosure provides a power-supply apparatus configured to more appropriately make a determination regarding abnormalities, such as breaking of a power line and a sensor malfunction.

A power-supply apparatus according to an aspect of the disclosure includes: a battery; a charger configured to charge the battery with electric power supplied from an external power supply; a charging relay provided on a power line, the charging relay configured to connect the battery and the charger to each other or disconnect the battery and the charger from each other through an on-off operation; a first voltage sensor attached to a portion of the power line that is closer to the charger than the charging relay is; a second voltage sensor attached to a portion of the power line that is closer to the battery than the charging relay is; and an electronic control unit configured to verify whether or not the battery is being charged by the charger while the charging relay is on. The electronic control unit is configured to i) permit detection of a deviation abnormality when it is verified that the battery is being charged by the charger while the charging relay is on, the deviation abnormality being an abnormality in which a deviation between a charger-side voltage detected by the first voltage sensor and a battery-side voltage detected by the second voltage sensor is equal to or greater than a threshold, and ii) prohibit detection of the deviation abnormality when it is not verified that the battery is being charged by the charger while the charging relay is on.

In the power-supply apparatus according to the above aspect, the electronic control unit verifies whether or not the battery is being charged by the charger while the charging relay is on. The electronic control unit permits detection of a deviation abnormality when it is verified that the battery is being charged by the charger while the charging relay is on. The deviation abnormality is an abnormality in which the deviation between the charger-side voltage detected by the first voltage sensor, which is attached to a portion of the power line that is closer to the charger than the charging relay is, and the battery-side voltage detected by the second voltage sensor, which is attached to a portion of the power line that is closer to the battery than the charging relay is, is equal to or greater than the threshold. When it is verified that the battery is being charged by the charger while the charging relay is on, detection of a deviation abnormality is permitted because it is considered that breaking of the power line has not occurred. Thus, it is possible to detect, for example, a sensor malfunction based on detection of a deviation abnormality. On the other hand, when it is not verified that the battery is being charged by the charger while the charging relay is on, detection of a deviation abnormality is prohibited. When it is not verified that the battery is being charged by the charger while the charging relay is on, there is a high possibility that breaking of the power line has occurred. Therefore, it is possible to reduce false detection, such as detection of a sensor malfunction based on detection of a deviation abnormality. As a result, it is possible to more appropriately make a determination regarding abnormalities, such as breaking of a power line and a sensor malfunction. Whether or not the battery is being charged by the charger can be verified based on a determination as to whether or not a value of a current passing through the battery is zero or based on a determination as to whether or not a value of electric power supplied from the external power supply to the charger is zero. Whether or not the value of the electric power supplied from the external power supply to the charger is zero can be determined based on whether or not a value of a current input into the charger from the external power supply is zero.

In the power-supply apparatus according to the above aspect, the electronic control unit may be configured to i) determine whether or not the charger-side voltage is lower than the battery-side voltage, and ii) permit detection of the deviation abnormality when the charger-side voltage is lower than the battery-side voltage, regardless of whether or not it is verified that the battery is being charged by the charger. A voltage of the battery is monitored through double monitoring including monitoring of the charger-side voltage from the first voltage sensor and monitoring of the battery-side voltage from the second voltage sensor. When at least one of an abnormal state where the charger-side voltage from the first voltage sensor is excessively high and an abnormal state where the battery-side voltage from the second voltage sensor is excessively low has occurred, the charger-side voltage becomes higher than the battery-side voltage. In this case, protection of the battery is executed depending on whether or not the charger-side voltage exceeds an overcharging threshold. On the other hand, when at least one of an abnormal state where the charger-side voltage from the first voltage sensor is excessively low and an abnormal state where the battery-side voltage from the second voltage sensor is excessively high has occurred, the charger-side voltage becomes lower than the battery-side voltage. In this case, it is not possible to execute protection of the battery depending on whether or not the charger-side voltage exceeds the overcharging threshold. In this case, the deviation between the charger-side voltage and the battery-side voltage increases due to charging of the battery. Thus, a large increase in the deviation can be detected as a deviation abnormality, before the battery is overcharged.

In the power-supply apparatus according to the above aspect, the electronic control unit may be configured to verify whether or not the battery is being charged by the charger, based on whether or not a value of a current passing through the battery is zero or based on whether or not a value of electric power supplied from the external power supply to the charger is zero.

### BRIEF DESCRIPTION OF THE DRAWINGS

Features, advantages, and technical and industrial significance of exemplary embodiments will be described below with reference to the accompanying drawings, in which like numerals denote like elements, and wherein:

FIG. 1 is a schematic diagram illustrating a configuration of a power-supply apparatus according to an embodiment of the disclosure;

FIG. 2 is a flowchart illustrating an example of a deviation abnormality detection permission-prohibition routine executed by a charging electronic control unit (ECU);

FIG. 3 is a graph illustrating an example of each of a temporal change in a deviation between a charging voltage and a battery voltage, a temporal change in a battery current, and a temporal change in a charger input electric power when breaking of a power line has occurred;

FIG. 4 is a graph illustrating an example of each of a temporal change in the charging voltage and a temporal change in the battery voltage when the charging voltage is lower than the battery voltage; and

FIG. 5 is a flowchart illustrating an example of a deviation abnormality detection permission-prohibition routine according to a modified example.

### DETAILED DESCRIPTION OF EMBODIMENTS

Hereinafter, an embodiment of the disclosure will be described with reference to the accompanying drawings.

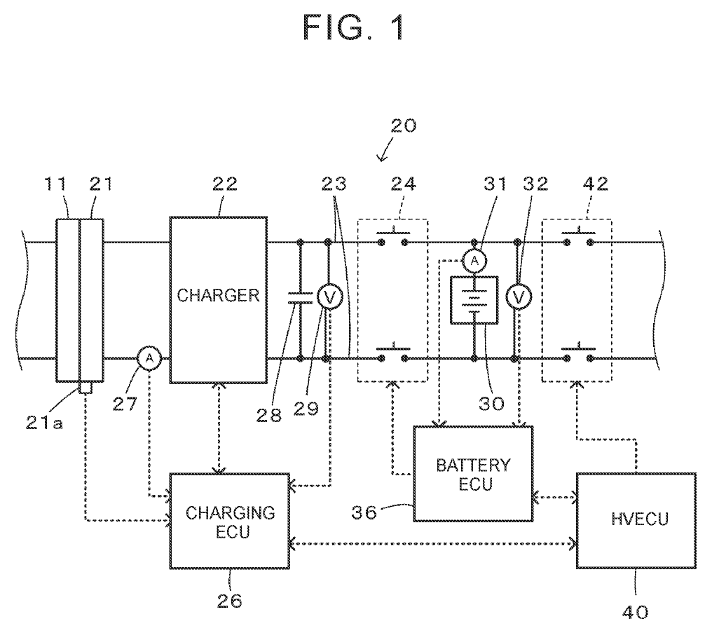

FIG. 1 is a schematic diagram illustrating a configuration of a power-supply apparatus 20 according to an embodiment of the disclosure. The power-supply apparatus 20 according to the present embodiment is mounted in a movable body, such as an electric vehicle or a hybrid vehicle. The power-supply apparatus 20 functions as a power supply for, for example, a motor for traveling. In the present embodiment, for the sake of the convenience, description will be provided on the assumption that the power-supply apparatus 20 is provided as a power supply of a hybrid vehicle. As illustrated in FIG. 1, the power-supply apparatus 20 according to the present embodiment includes a charger 22, a charging relay 24, a battery 30, a charging electronic control unit 26 (hereinafter, referred to as “charging ECU 26”), a battery electronic control unit 36 (hereinafter, referred to as “battery ECU 36”), and a hybrid vehicle electronic control unit 40 (hereinafter, referred to as “HVECU 40”).

The charger 22 is connected to the battery 30 through a power line 23. The charger 22 is configured to charge the battery 30 with electric power supplied from an external power supply while a connector 21 is connected to a connector 11 of the external power supply. The charger 22 includes an AC-DC converter and a DC-DC converter, both of which are not illustrated. The AC-DC converter converts alternating-current power supplied from the external power supply via the connector 21, into direct-current power. The DC-DC converter converts the voltage of the direct-current power from the AC-DC converter, and then supplies, toward the battery 30, the direct-current power that has undergone the voltage conversion. While the connector 21 is connected to the connector 11 of the external power supply, the charger 22 supplies the electric power from the external power supply to the battery 30 under control of the charging ECU 26 executed on the AC-DC converter and the DC-DC converter.

Although not illustrated in detail, the charging ECU 26 has a configuration as a microprocessor mainly including a central processing unit (CPU), and further including, for example, a read-only memory (ROM) configured to store processing programs, a random-access memory (RAM) configured to temporarily store data, an input port, an output port, and a communication port, in addition to the CPU. Various signals are input into the charging ECU 26 through the input port. The various signals include signals from various sensors attached to the charger 22, and a connection signal from a connection switch 21a attached to the connector 21 and configured to determine whether or not the connector 21 has been connected to the connector 11 of the external power supply. Further, an input current Iin from a current sensor 27 and a charging voltage Vchg from a voltage sensor 29 are input into the charging ECU 26. The current sensor 27 is configured to detect a current to be input into the charger 22 from the external power supply. The voltage sensor 29 is configured to detect a voltage across terminals of a capacitor 28, as a charging voltage Vchg from the charger 22. For example, control signals for the AC-DC converter and the DC-DC converter of the charger 22 are output from the charging ECU 26 through the output port. The charging ECU 26 communicates with the HVECU 40, so that information obtained by the charging ECU 26 is transmitted to the HVECU 40 as necessary.

The battery 30 has a configuration as, for example, a lithium-ion secondary battery. The battery 30 is connected to a load, such as a motor for traveling (not illustrated), via a system main relay 42. Further, the battery 30 is connected, via the charging relay 24, to the charger 22 through the power line 23. The smoothing capacitor 28 is attached to the power line 23, at a position between the charger 22 and the charging relay 24. The battery 30 is controlled by the battery ECU 36.

Although not illustrated in detail, the battery ECU 36 has a configuration as a microprocessor mainly including a CPU, and further including, for example, a ROM configured to store processing programs, a RAM configured to temporarily store data, an input port, an output port, and a communication port, in addition to the CPU. Various signals are input into the battery ECU 36 through the input port. The various signals include a battery current Ib from a current sensor 31 attached to a power line connected to an output terminal of the battery 30, and a battery voltage Vb from a voltage sensor 32 disposed between the terminals of the battery 30. For example, a driving signal for the charging relay 24 is output from the battery ECU 36 through the output port. The battery ECU 36 communicates with the HVECU 40, so that information obtained by the battery ECU 36 is transmitted to the HVECU 40 as necessary.

Although not illustrated in detail, the HVECU 40 has a configuration as a microprocessor mainly including a CPU, and further including, for example, a ROM configured to store processing programs, a RAM configured to temporarily store data, an input port, an output port, and a communication port, in addition to the CPU. The HVECU 40 turns on the system main relay 42 upon system startup, controls the entire system of the hybrid vehicle, and controls driving of a load, such as a motor for traveling (not illustrated). As described above, the HVECU 40 communicates with the charging

ECU 26 and the battery ECU 36, so that the HVECU 40 receives necessary information from the charging ECU 26 and the battery ECU 36.

In the present embodiment, the connector 21, the charger 22, the charging relay 24, the charging ECU 26, the battery 30, the battery ECU 36, and the HVECU 40 are function as the power-supply apparatus 20.

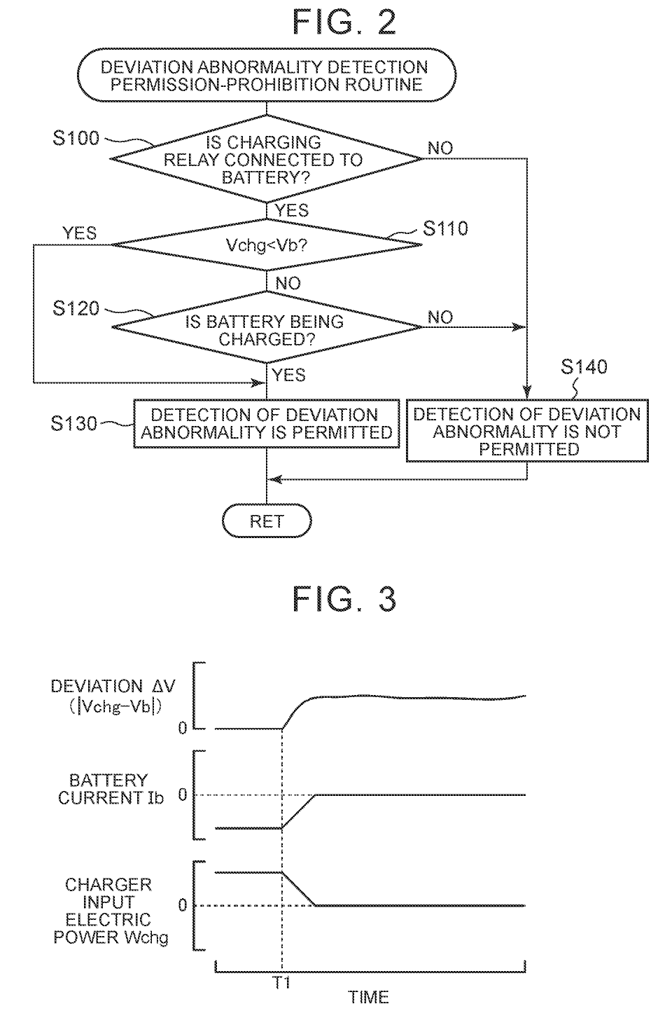

The HVECU 40 detects a deviation abnormality when a deviation ΔV(ΔV=|Vchg−Vb|) between the charging voltage Vchg and the battery voltage Vb, which is the voltage across terminals of the battery 30, becomes equal to or greater than a threshold while the charger 22 is charging the battery 30. On the other hand, the HVECU 40 determines whether or not breaking of the power line 23 has occurred. When breaking of the power line 23 has occurred, the HVECU 40 outputs a signal indicating the occurrence of breaking of the power line 23. When breaking of the power line 23 has occurred, a deviation abnormality is also detected. In view of this, the HVECU 40 according to the present embodiment executes a deviation abnormality detection permission-prohibition routine in FIG. 2 in order to distinguish breaking of the power line 23 and a deviation abnormality from each other. The deviation abnormality detection permission-prohibition routine is repeatedly executed at prescribed time intervals (e.g., every several milliseconds).

Upon start of execution of the deviation abnormality detection permission-prohibition routine, the HVECU 40 first determines whether or not the charger 22 and the battery 30 are connected to each other by the charging relay 24 (step S100). The HVECU 40 can make this determination based on the information indicating whether the charging relay 24 is on or off, which is received from the charging ECU 26. When determining that the charger 22 and the battery 30 are not connected to each other by the charging relay 24, the HVECU 40 determines that detection of a deviation abnormality is not necessary because charging of the battery 30 is not being performed, and does not permit detection of a deviation abnormality (step S140). Then, the HVECU 40 ends the present routine.

When determining in step S100 that the charger 22 and the battery 30 are connected to each other by the charging relay 24, the HVECU 40 determines whether or not the charging voltage Vchg is lower than the battery voltage Vb (step S110). When determining that the charging voltage Vchg is equal to or higher than the battery voltage Vb, the HVECU 40 verifies whether or not the battery 30 is being charged by the charger 22 (step S120). FIG. 3 is a graph illustrating an example of each of a temporal change in the deviation AV between the charging voltage Vchg and the battery voltage Vb, a temporal change in the battery current Ib, and a temporal change in electric power Wchg that is input into the charger 22 (hereinafter, referred to as “charger input electric power Wchg”), when breaking of the power line 23 has occurred. As illustrated in FIG. 3, when breaking of the power line 23 occurs at time T1, the deviation AV increases with an increase in the charging voltage Vchg. The absolute value of the battery current Ib starts decreasing at time T1 and finally becomes equal to zero. The charger input electric power Wchg becomes equal to zero because the power supply to the charger 22 is stopped upon detection of breaking of the power line 23. In the present embodiment, the HVECU 40 verifies whether or not the battery 30 is being charged by the charger 22, by verifying whether or not the battery current Ib is zero. More specifically, it is verified that the battery 30 is being charged by the charger 22 when the battery current Ib is not zero, whereas it is not verified that the battery 30 is being charged by the charger 22 when the battery current Ib is zero. The battery current Ib is a current passing through the battery 30, and is detected by the current sensor 31. When it is verified that the battery 30 is being charged by the charger 22, the HVECU 40 determines that breaking of the power line 23 has not occurred, and permits detection of a deviation abnormality (step S130). Then, the HVECU 40 ends the present routine. Thus, it is possible to detect, for example, a malfunction of the voltage sensor 29 based on the detection of a deviation abnormality. On the other hand, when it is not verified that the battery 30 is being charged by the charger 22, the HVECU 40 determines that there is a possibility that breaking of the power line 23 has occurred, and does not permit detection of a deviation abnormality (step S140). Then, the HVECU 40 ends the present routine. Thus, it is possible to reduce false detection of, for example, a malfunction of the voltage sensor 29 based on detection of a deviation abnormality.

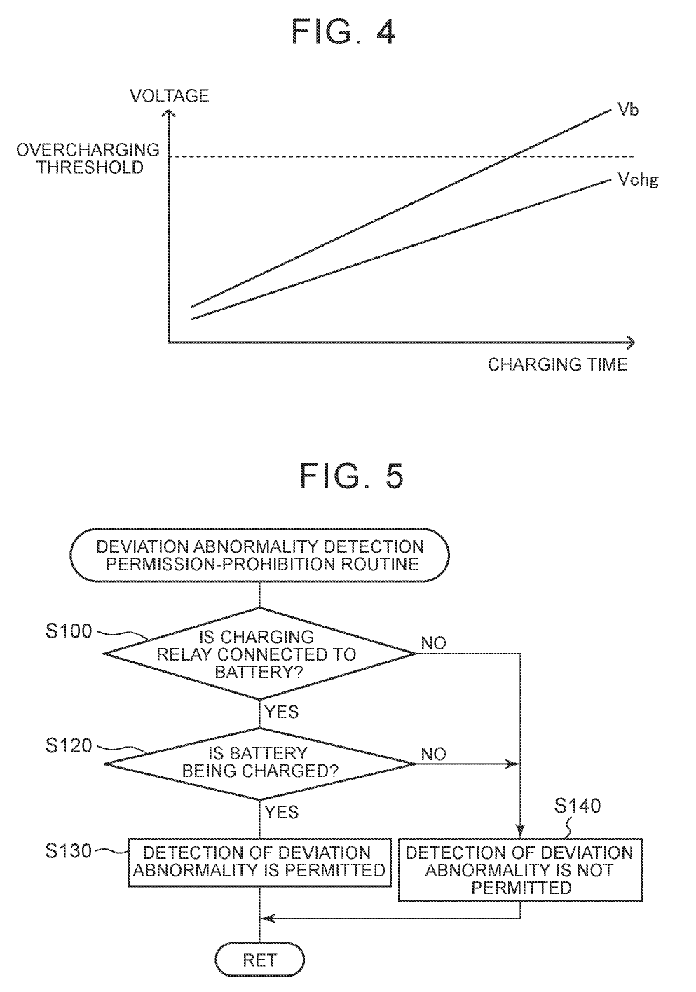

When the HVECU 40 determines in step S110 that the charging voltage Vchg is lower than the battery voltage Vb, detection of a deviation abnormality is permitted regardless of whether or not the battery 30 is being charged by the charger 22 (step S130). Then, the HVECU 40 ends the present routine. The voltage of the battery 30 is monitored through double monitoring including monitoring of the battery voltage Vb from the voltage sensor 32 and monitoring of the charging voltage Vchg from the voltage sensor 29. When at least one of an abnormal state where the charging voltage Vchg from the voltage sensor 29 is excessively high and an abnormal state where the battery voltage Vb from the voltage sensor 32 is excessively low has occurred, the charging voltage Vchg becomes equal to or higher than the battery voltage Vb. In this case, protection of the battery 30 is executed depending on whether or not the charging voltage Vchg exceeds an overcharging threshold. On the other hand, when at least one of an abnormal state where the charging voltage Vchg from the voltage sensor 29 is excessively low and an abnormal state where the battery voltage Vb from the voltage sensor 32 is excessively high has occurred, the charging voltage Vchg becomes lower than the battery voltage Vb. In this case, it is not possible to execute protection of the battery 30 depending on whether or not the charging voltage Vchg exceeds the overcharging threshold. In view of this, in order to detect such an abnormality, detection of a deviation abnormality is permitted. The deviation between the charging voltage Vchg and the battery voltage Vb increases with an increase in the charging time, as illustrated in FIG. 4. Thus, a large increase in the deviation can be detected as a deviation abnormality, before the battery 30 is overcharged.

In the power-supply apparatus 20 according to the embodiment described so far, when it is verified that the battery 30 is being charged by the charger 22 while the charging relay 24 is on, detection of a deviation abnormality is permitted. A deviation abnormality means an abnormal state where the deviation AV between the charging voltage Vchg and the battery voltage Vb is equal to or greater than the threshold. In this case, it is determined that breaking of the power line 23 has not occurred. Thus, even when a deviation abnormality is detected, the deviation abnormality can be distinguished from a deviation abnormality due to breaking of the power line 23. Thus, it is possible to detect, for example, a malfunction of the voltage sensor 29 based on detection of a deviation abnormality. On the other hand, when it is not verified that the battery 30 is being charged by the charger 22 while the charging relay 24 is on, detection of a deviation abnormality is not permitted. This is because there is a possibility that breaking of the power line 23 has occurred. In this way, it is possible to distinguish breaking of the power line 23 and an abnormality of deviation between the charging voltage Vchg and the battery voltage Vb. As a result, it is possible to more appropriately make determination regarding abnormalities, such as breaking of the power line 23 and a sensor malfunction. Moreover, when the charging voltage Vchg is lower than the battery voltage Vb, detection of a deviation abnormality is permitted regardless of whether or not the battery 30 is being charged by the charger 22. Thus, it is possible to detect a deviation abnormality due to occurrence of at least one of an abnormal state where the charging voltage Vchg from the voltage sensor 29 is excessively low and an abnormal state where the battery voltage Vb from the voltage sensor 32 is excessively high.

In the power-supply apparatus 20 according to the present embodiment, when the charging voltage Vchg is lower than the battery voltage Vb, detection of a deviation abnormality is permitted regardless of whether or not it is verified that the battery 30 is being charged by the charger 22. However, as illustrated in a deviation abnormality detection permission-prohibition routine according to a modified example in FIG. 5, detection of a deviation abnormality may be permitted or prohibited by verifying whether or not the battery 30 is being charged by the charger 22, without determining whether or not the charging voltage Vchg is lower than the battery voltage Vb. In this case as well, even when a deviation abnormality is detected, the deviation abnormality can be distinguished from a deviation abnormality due to breaking of the power line 23.

In the power-supply apparatus 20 according to the foregoing embodiment, the HVECU 40 executes the deviation abnormality detection permission-prohibition routine in FIG. 2. Alternatively, the charging ECU 26 may execute the deviation abnormality detection permission-prohibition routine, or the battery ECU 36 may execute the deviation abnormality detection permission-prohibition routine.

The power-supply apparatus 20 according to the foregoing embodiment include three electronic control units, that is, the charging ECU 26, the battery ECU 36, and the HVECU 40. Alternatively, the power-supply apparatus 20 may include one electronic control unit, two electronic control units, or four or more electronic control units.

The deviation abnormality detection permission-prohibition routine in FIG. 2 may be executed by any one of the electronic control units.

In the foregoing embodiment, the power-supply apparatus 20 is provided as a power supply for a hybrid vehicle. Alternatively, the power-supply apparatus 20 may be provided as a power supply for an electric vehicle as described above, or the power-supply apparatus 20 may be incorporated in equipment other than a movable body, such as a hybrid vehicle or an electric vehicle.

In the foregoing embodiment, the battery 30 is an example of “battery”, the charger 22 is an example of “charger”, the charging relay 24 is an example of “charging relay”, and the HVECU 40 configured to execute the deviation abnormality detection permission-prohibition routine in FIG. 2 is an example of “electronic control unit”.

While one embodiment of the disclosure has been described above, the disclosure is not limited to the foregoing embodiment and may be implemented in various other embodiments within the technical scope of the disclosure.

The disclosure may be used in, for example, the manufacturing industry for power-supply apparatuses.

What is claimed is:

1. A power-supply apparatus comprising:
a battery;
a charger configured to charge the battery with electric power supplied from an external power supply;
a charging relay provided on a power line, the charging relay configured to connect the battery and the charger to each other or disconnect the battery and the charger from each other through an on-off operation;
a first voltage sensor attached to a portion of the power line that is closer to the charger than the charging relay is;
a second voltage sensor attached to a portion of the power line that is closer to the battery than the charging relay is; and
an electronic control unit configured to verify whether or not the battery is being charged by the charger while the charging relay is on, wherein
the electronic control unit is configured to
i) permit detection of a deviation abnormality when it is verified that the battery is being charged by the charger while the charging relay is on, the deviation abnormality being an abnormality in which a deviation between a charger-side voltage detected by the first voltage sensor and a battery-side voltage detected by the second voltage sensor is equal to or greater than a threshold, and
ii) prohibit detection of the deviation abnormality when it is not verified that the battery is being charged by the charger while the charging relay is on.

2. The power-supply apparatus according to claim 1, wherein
the electronic control unit is configured to
i) determine whether or not the charger-side voltage is lower than the battery-side voltage, and
ii) permit detection of the deviation abnormality when the charger-side voltage is lower than the battery-side voltage, regardless of whether or not it is verified that the battery is being charged by the charger.

3. The power-supply apparatus according to claim 1, wherein the electronic control unit is configured to verify whether or not the battery is being charged by the charger, based on whether or not a value of a current passing through the battery is zero or based on whether or not a value of electric power supplied from the external power supply to the charger is zero.

4. The power-supply apparatus according to claim 3, further comprising a current sensor attached to the power line connected to an output terminal of the battery, wherein the electronic control unit is configured to determine that it is not verified that the battery is being charged when a current value detected by the current sensor is zero.

5. The power-supply apparatus according to claim 1, wherein the electronic control unit is configured to determine that the deviation abnormality has occurred when the deviation between the charger-side voltage and the battery-side voltage is equal to or greater than the threshold.
